(19) United States
(12) Patent Application Publication
(10) Pub. No.: US 2016/0315033 A1
(43) Pub. Date: Oct. 27, 2016

(54) Device Including a Logic Semiconductor Chip Having a Contact Electrode for Clip Bonding

(71) Applicant: Infineon Technologies Austria AG, Villach (AT)

(72) Inventors: Ralf Otremba, Kaufbeuren (DE); Josef Hoeglauer, Heimstetten (DE); Aliaksandr Subotski, Villach (AT)

(21) Appl. No.: 15/135,155

(22) Filed: Apr. 21, 2016

(30) Foreign Application Priority Data
Apr. 22, 2015 (DE) 102015106148.1

(51) Int. Cl. H01L 23/495; H01L 23/373; H01L 21/66

(52) U.S. Cl. CPC H01L 23/49524; H01L 23/49582; H01L 23/4952; H01L 23/49562; H01L 22/32; H01L 23/3736

(57) ABSTRACT

A device includes a logic semiconductor chip having a contact electrode. The contact electrode is configured to be electrically coupled to a contact clip based on a clip bonding technique.

### TECHNICAL FIELD

The disclosure relates, in general, to semiconductor devices. More particular, the disclosure relates to devices including a logic semiconductor chip having a contact electrode configured for a clip bonding process.

### BACKGROUND

Semiconductor devices may include one or more semiconductor chips, for example logic semiconductor chips. The logic semiconductor chips may need to communication with further electronic components of the semiconductor devices and thus need to be electrically accessible from the outside, for example via peripheral contact electrodes. Semiconductor devices constantly have to be improved. In particular, it may be desirable to improve an electrical and thermal performance of the semiconductor devices. In addition, it may be desirable to simplify the design and the fabrication of the semiconductor devices.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference numbers may designate corresponding similar parts.

FIG. 1 schematically illustrates a cross sectional side view of a device 100 in accordance with the disclosure.

FIG. 2 schematically illustrates a cross sectional side view of a device 200 in accordance with the disclosure.

FIG. 3 schematically illustrates a cross sectional side view of a device 300 in accordance with the disclosure.

FIGS. 4A to 4E schematically illustrate an exemplary clip bonding technique which may be applied to a device in accordance with the disclosure.

FIG. 5 schematically illustrates a top view of a device 500 in accordance with the disclosure.

FIG. 6 schematically illustrates a top view of a device 600.

FIG. 7 schematically illustrates a top view of a device 700 in accordance with the disclosure.

FIG. 8 illustrates a schematic diagram of a half bridge circuit 800.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

As employed in this specification, the terms “connected”, “coupled”, “electrically connected” or “electrically coupled” may not necessarily mean that elements must be directly connected or coupled together. Intervening elements may be provided between the “connected”, “coupled”, “electrically connected” or “electrically coupled” elements.

Further, the word “over” (or “on”) used with regard to e.g. a material layer formed or located “over” a surface of an object may be used herein to mean that the material layer may be located. (e.g. formed, deposited, etc.) “directly on”, e.g. in direct contact with, the implied surface. The word “over” used with regard to e.g. a material layer formed or located “over” a surface may also be used herein to mean that the material layer may be located. (e.g. formed, deposited, etc.) “indirectly on” the implied surface with e.g. one or more additional layers being arranged between the implied surface and the material layer.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures. In addition, the features of the various exemplary aspects described herein may be combined with each other, unless specifically noted otherwise.

The devices described herein may include one or more semiconductor chips. The semiconductor chips may be of different types and may be manufactured by different technologies. For example, the semiconductor chips may include integrated electrical, electrooptical or electromechanical circuits, passives, etc. The integrated circuits may be designed as logic integrated circuits, analog integrated circuits, mixed signal integrated circuits, power integrated circuits, memory circuits, integrated passives, microelectromechanical systems, etc. The semiconductor chips need not be manufactured from a specific semiconductor material and may contain inorganic and/or organic materials that are not semiconductors, e.g. insulators, plastics, metals, etc. In one example, the semiconductor chips may be made of or may include an elemental semiconductor material, for example Si. In a further example, the semiconductor chips may be made of or may include a compound. semiconductor material, for example GaN, SiC, SiGe, GaAs.

The semiconductor chips may have a vertical structure, i.e. the semiconductor chips may be fabricated such that electric currents may substantially flow in a direction perpendicular to the main surfaces of the semiconductor chips. A semiconductor chip having a vertical structure may have electrodes over its two main surfaces, i.e. over its top side and bottom side. For example, power semiconductor chips may have a vertical structure and may have load electrodes arranged over both main surfaces. In one example, the source electrode and the gate electrode of a power MOSFET may be arranged over one surface while the drain electrode of the power MOSFET may be arranged over the other surface.

The semiconductor chips may have a lateral structure, i.e. the semiconductor chips may be fabricated such that electric currents may substantially flow in a direction parallel to a main surface of the semiconductor chips. A semiconductor chip having a lateral structure may have electrodes arranged over one of its main surfaces. In one example, a semiconductor chip having a lateral structure may include an integrated circuit, such as e.g. a logic semiconductor chip. In a further example, a power semiconductor chip may have a lateral structure, wherein the load electrodes may be arranged over one main surface of the semiconductor chip. For example, the source electrode, the gate electrode and the drain electrode of a power MOSFET may be arranged over one main face of the power MOSFET. A further example of a lateral power semiconductor chip may be a HEMT (High Electron Mobility Transistor) that may be fabricated from a compound semiconductor material.

The devices described herein may include one or more power semiconductor chips. For example, the power semiconductor chips may be configured as diodes, power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), super junction devices, power bipolar transistors, etc.

The devices described herein may include one or more logic semiconductor chips. A logic semiconductor chip may include at least one of a logic integrated circuit, a control integrated circuit, a driver integrated circuit. A logic semiconductor chip (or logic integrated circuit) may be configured to control and/or drive electronic components of a device. In this regard, the terms “logic semiconductor chip”, “control semiconductor chip”, “driver semiconductor chip” may be used synonymously herein. For example, a logic semiconductor chip may be configured to control and/or drive integrated circuits of one or more power semiconductor chips.

A driver circuit may be configured to drive one or more electronic components of the device, such as e.g. a power transistor. The driven components may be voltage driven or current driven. For example, power MOSFETs, IGBTs, etc., may be voltage driven switches, since their insulated gate may particularly behave like a capacitor. Conversely, switches such as triacs (triode for alternating current), thyristors, bipolar transistors, a PN diode, etc., may be current driven. In one example, driving a component including a gate electrode may be performed by a gate driver circuit. The driving process may include applying different voltages to the gate electrode, for example in form of turn-on and turn-off switching wave forms. In a further example, a driver circuit may be used to drive a direct driven circuit. A control circuit may be configured to control one or more drivers that drive components of the device. In one example, a control circuit may simultaneously control drivers of multiple direct driven circuits. For example, a half bridge circuit including two direct driven circuits may thus be controlled by a controller. A controller may e.g. include a micro controller.

The semiconductor chips of the devices described herein may include one or more electrical contacts. An electrical contact may have the form of a contact electrode (or a contact pad or a contact terminal) that allows electrical contact to be made with the internal electronic structures and integrated circuits included in the semiconductor chips from outside of the semiconductor chip. Such contact electrodes may be particularly located at a periphery of the semiconductor chip and thus represent external electrodes of the semiconductor chips. In this regard, the contact electrodes may be distinguished from electrical contacts that may be a part of an internal electronic structure or internal circuitry of the semiconductor chips. Rather, the external electrical electrodes may be arranged over the active area and/or over the internal circuitry and/or over the internal redistribution of the semiconductor chips.

The contact electrodes may include one or more metal layers that may be applied to the semiconductor material of the semiconductor chips. The geometric shape and the material composition of the metal layers may depend on the type of the respective semiconductor chip. The metal layers may e.g. have the form of a layer covering an area. The metal layers may particularly be fabricated of at least one of a metal and a metal alloy. In general, any desired metal or metal alloy, for example, aluminum, titanium, gold, silver, copper, palladium, platinum, nickel, chromium, vanadium, tungsten, molybdenum, etc., may be used as a material. The metal layers need not be homogenous or manufactured from lust one material, but various compositions and concentrations of the materials included in the metal layers may be also possible. For example, a contact electrode may be formed as a layer stack including multiple layers that may be manufactured from different materials. Depending on the considered electrode type, more specific materials may be used for a fabrication of the contact electrodes. Examples for specific electrode types are specified in the following.

The semiconductor chips of the devices described herein may include multiple contact electrodes that may be similar or of different types. In particular, the semiconductor chips may include one or more contact electrodes that may be configured to be electrically coupled to a contact clip based on a clip bonding technique. Such contact electrodes may include a contact layer (or layer stack) including at least one of copper and nickel. Here, the percentage of copper and/or nickel in the contact layer may be at least 40%, or at least 50%, or at least 60%, or at least 70%, or at least 80%, or at least 90%. The contact layer may be a final layer arranged on an outer periphery of the contact electrode. That is, the contact layer may be uncovered by further layers on a peripheral surface and thus may be configured for a direct contact with a contact clip or a material providing a coupling between the contact electrode and the contact clip (e.g. a solder material). For example, the contact layer may be made of (or may include) at least one of copper, nickel, nickel-silver, chromium-nickel-silver. A thickness of the contact layer may lie in a range from about 1 micrometer to about 5 micrometer. The contact layer may be manufactured based on at least one of sputtering, chemical vapor deposition (CVD), and physical vapor deposition (PVD). Since a contact between the contact electrode and a contact clip may be established by a solder material or a solder bond, the contact electrode may particularly include a solderable contact layer.

The semiconductor chips of the devices described herein may include one or more contact electrodes that may be configured to be electrically coupled to a wire based on a wire bonding technique. Such contact electrodes may include a contact layer (or layer stack) including at least one of aluminum and aluminum copper. The contact layer may be a final layer arranged on an outer periphery of the contact electrode, i.e. the contact layer may be uncovered by further layers on a peripheral surface and may be configured for a direct contact with a wire or a material providing a coupling between the contact electrode and the wire.

The contact electrodes of the devices described herein may optionally include a final layer that may be arranged at an outer periphery of the contact electrode. Such optional layer may thus be additionally arranged over the layers described above. The optional final layer may include at least one of gold, silver, palladium, platinum and may have a thickness lying in a range from about 100 nanometer to about 500 nanometer. The optional final layer may be used in any of the discussed cases, i.e. for contact electrodes configured for clip bonding techniques as well as for contact electrodes configured for wire bonding techniques.

The devices described herein may include a carrier over which one or more components of the device may be arranged. In general, a carrier may be manufactured from at least one of a metal, a metal alloy, a dielectric, a plastic, a ceramic, etc. The carrier may have a homogeneous structure, but may also provide internal structures like conducting paths with an electrical redistribution function. For example, a carrier may include at least one of a diepad, a leadframe, a ceramic substrate including one or more redistribution layers, etc.

A leadframe may be structured such that diepads and leads may be formed. During a fabrication the diepads and the leads may be connected to each other. The diepads and the leads may also be made from one piece. The diepads and the leads may be connected among each other by connection means with the purpose of separating some of the diepads and the leads in the course of the fabrication. Here, separating the diepads and the leads may be carried out by at least one of mechanical sawing, a laser beam, cutting, stamping, milling, etching, etc. In one example, the leadframe may be a multilevel leadframe having various sections arranged on different levels. For example, the different levels of the leadframe may be implemented by bending the leadframe in a suitable manner before or after the various carrier sections may have been formed. Leads of the leadframe may protrude out of an encapsulation material of the device such that an electrical connection between internal components of the device and external components may be established.

In particular, a leadframe may at least partly be electrically conductive. For example, the leadframe may be entirely fabricated from metals and/or metal alloys, in particular at least one of copper, copper alloys, nickel, iron nickel, aluminum, aluminum alloys, steel, stainless steel, etc. The leadframe material may include traces of iron, sulfur, iron nitride, etc. The leadframe may be plated with an electrically conductive material, for example at least one of copper, silver, palladium, gold, nickel, iron nickel, nickel phosphorus, etc. In this case, the leadframe may be referred to as pre-plated leadframe. Even though a leadframe may be electrically conductive, an arbitrary selection of diepads of the leadframe may be electrically insulated from each other.

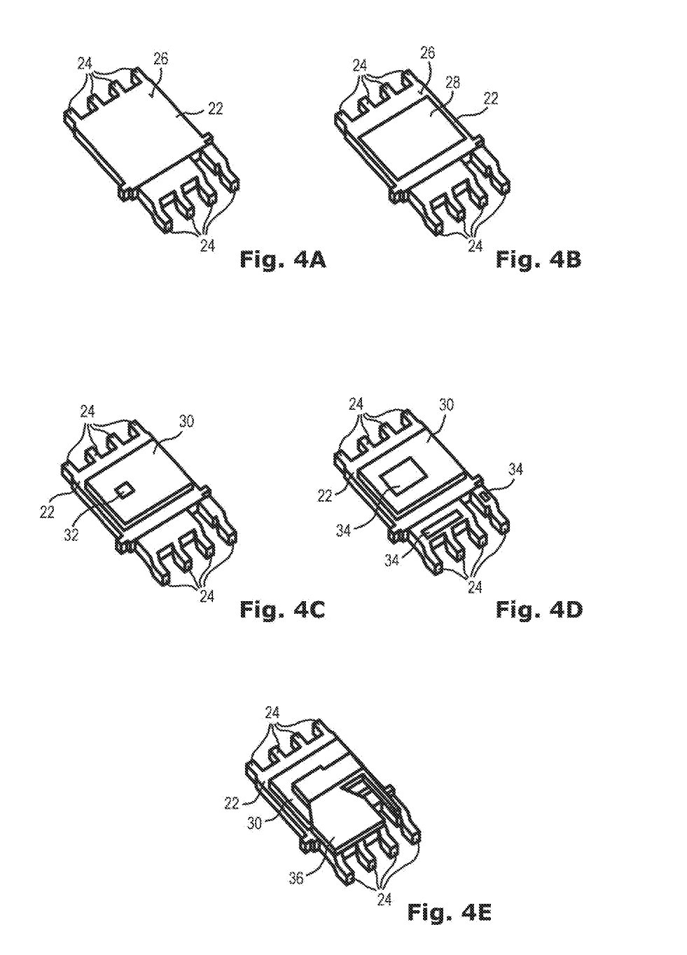

The devices described herein may include one or more electrically conductive elements configured to provide an electrical coupling between components of the devices. For example, such electrically conductive element may provide an electrical connection between a contact electrode of a semiconductor chip and a contact electrode of a further semiconductor chip or between a contact electrode of a semiconductor chip and a diepad or a lead. An electrically conductive element may include one or more contact clips that may be formed from a leadframe material. In particular, the contact clip may be made of or may include at least one of a metal and a metal alloy and may then be referred to as metal clip. The contact clip may be fabricated by at least one of stamping, punching, pressing, cutting, sawing, milling, etc. A contact between the contact clip and a contact electrode of a semiconductor chip may be established by a diffusion soldering process in one example. An exemplary process for providing an electrical connection between a contact clip and a contact electrode based on a clip bonding technique is described in connection with FIGS. 4A to 4E. In a further example, an electrically conductive element may include one or more wires, in particular bond wires or bonding wires. A wire may include a metal and/or a metal alloy, in particular gold, aluminum, copper, or one or more of their alloys. In addition, the wire may or may not include a coating. A thickness of a wire may depend on the strength of the currents flowing through the wire. In one more specific example, the wire may have a thickness smaller than 75 micrometer, for example a thickness from about 50 micrometer to about 75 micrometer, and may be made of aluminum.

A contact clip may provide one or more sensing signals from and/or to a semiconductor chip electrically coupled to the contact clip. Such sensing signal may be based on or may depend on a physical parameter (or physical quantity or physical magnitude) of the semiconductor chip. Hence, the sensing signal may represent or include information about a physical property of the semiconductor chip that can be quantified by a measurement. In this regard, a sensing signal provided by the contact clip and the associated physical parameter may not necessarily coincide with regard to their physical units. For example, the sensing signal may correspond to a measured voltage, but may represent a different physical quantity, for example an electrical current or a temperature.

In one example, the contact clip may provide a sensing signal that may be based on or may represent an electrical potential of the semiconductor chip. The sensing signal may e.g. represent an electrical potential of a contact electrode of the semiconductor chip. In this regard, the contact clip may optionally be electrically coupled to a voltage measuring unit configured to measure the electrical potential of the considered contact electrode. In a further example, the contact clip may provide a sensing signal that may be based on an electrical current of the semiconductor chip. The sensing signal may e.g. be based on a current passing between a source electrode of a power transistor and a drain electrode of the power transistor. In this regard, the contact clip providing the sensing signal may be electrically coupled to a shunt that may be used for measuring the electrical current. A current flowing through the shunt may cause a voltage drop that may be proportional to the electrical current and may be measured. In one example, the shunt may be integrated in the considered semiconductor chip. In yet a further example, the contact clip may provide a sensing signal that may be based on a temperature of the semiconductor chip. In this regard, the contact clip may be electrically coupled to a diode. The conductivity of the diode may depend on its temperature such that a voltage at an exposed end section of the contact clip electrically connected to the diode may depend on the temperature of the diode as well. In one example, the diode may be integrated in the semiconductor chip.

A sensing signal provided by the contact clip may be used to control and monitor the state of a semiconductor chip. For this purpose, the sensing signal may e.g. be provided to a logic semiconductor chip that may be configured to generate a control signal and further to provide the control signal to relevant components performing the control of the semiconductor chip. In one example, a sensed electrical potential of a source electrode of a power transistor may be used to generate a control signal that may be used by a gate driver circuit to control a gate electrode of the power transistor. In particular, the measured electrical potential U_{S} at the source electrode may be used to correct a voltage U_{G} that may have been applied to the gate electrode without taking into account the sensing signal. A corrected value that may be applied to the gate electrode may thus have a value of U_{G}−U_{S} in one example. In a further example, sensing of an electrical current in the semiconductor chip may be used to monitor a temporal development of the electrical current. This way, it may be avoided that the strength of the current exceeds a threshold value. When the measured. electrical current exceeds a predetermined threshold value, an operation of one or more components of the device may be adjusted. In a suitable manner in order to force the current strength below the threshold value. In yet a further example, measuring a temperature in the semiconductor chip may be used to monitor a temporal development of the temperature. It may then be possible to avoid that the temperature exceeds a threshold value. When the measured temperature exceeds a predetermined threshold value, an operation of one or more components of the device may be adjusted (or delayed or stopped) such that the temperature may fall below the predetermined threshold value.

The devices described herein may be packaged or not. A semiconductor package may be a semiconductor device including an encapsulation material that may at least partly cover (or embed or encapsulate) one or more components of the device, for example semiconductor chips, a leadframe, one or more leads, etc. The encapsulation material may be electrically insulating and may form an encapsulation body. The encapsulation material may include at least one of an epoxy, a glass fiber filled epoxy, a glass fiber filled polymer, an imide, a filled or non-filled thermoplastic polymer material, a filled or non-filled duroplastic polymer material, a filled or non-filled polymer blend, a thermosetting material, a mold compound, a glob-top material, a laminate material, etc. Various techniques may be used to encapsulate components of the device with the encapsulation material, for example at least one of compression molding, injection molding, powder molding, liquid molding, lamination, etc.

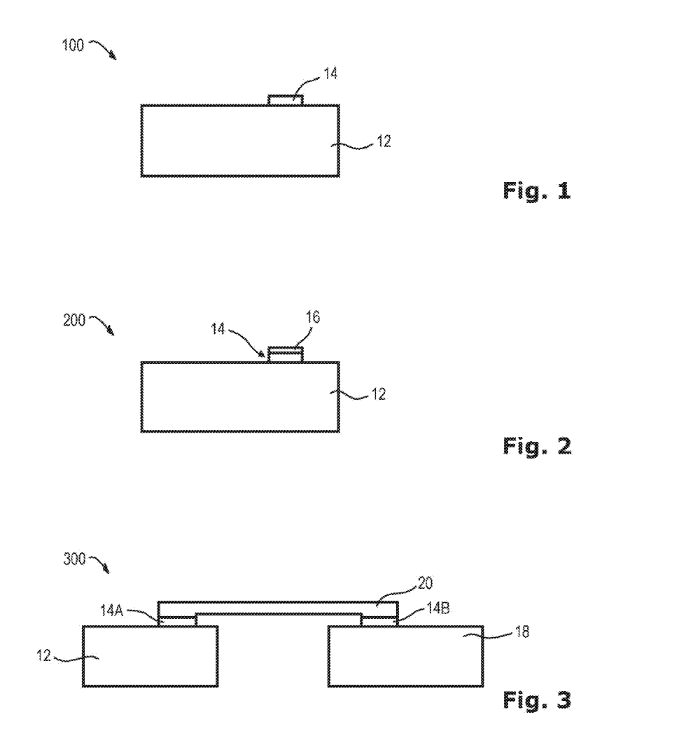

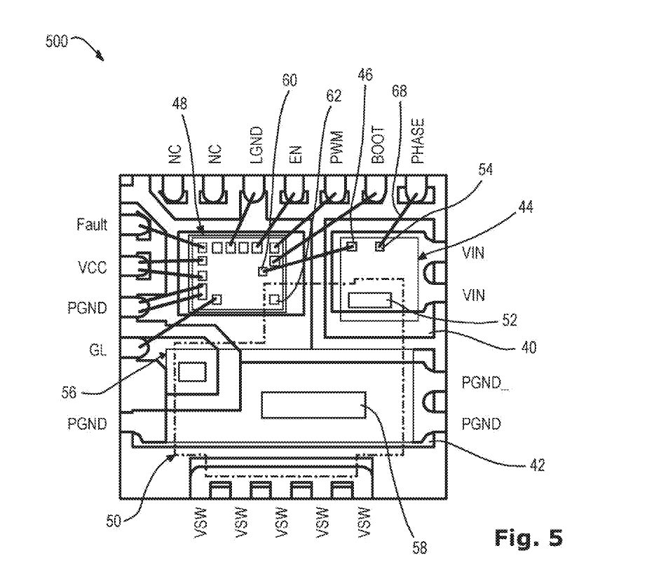

FIGS. 1 to 3 schematically illustrate cross sectional side views of devices 100 to 300 in accordance with the disclosure. In the examples of FIGS. 1 to 3, the devices 100 to 300 are illustrated in a general manner and may include further components that are not illustrated for the sake of simplicity. For example, each of the devices 100 to 300 may further include one or more components of the devices 500 to 700 described in connection with FIGS. 5 to 7.

The device 100 of FIG. 1 includes a logic semiconductor chip 12 having a contact electrode 14. The contact electrode 14 is configured to be electrically coupled to a contact clip (not illustrated) based on a clip bonding technique. An exemplary technique for providing an electrical coupling between the contact electrode 14 and a contact clip is described in connection with FIGS. 4A to 4E. The logic semiconductor chip 12 may include further optional contact electrodes (not illustrated). Depending on their respective use, the further contact electrodes may also be configured to be electrically coupled to a contact clip based on a clip bonding technique or they may be configured to be electrically coupled to a wire based on a wire bonding technique.

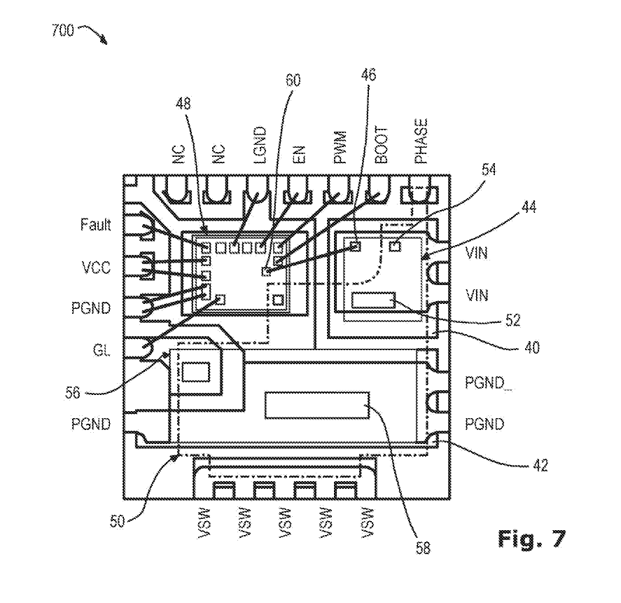

For example, the logic semiconductor chip 12 may be a part of a multichip device that may additionally include one or more power semiconductor chips, wherein the power semiconductor chips may be electrically coupled among each other via contact clips. The logic semiconductor chip 12 may need to be electrically coupled to one or more of the power semiconductor chips. Other (conventional) logic semiconductor chips may be similar to the logic semiconductor chip 12 of the device 100, but they may only have a contact electrode configured to be electrically coupled to a wire based on a wire bonding technique. Hence, using these other conventional logic semiconductor chips, the required electrical connections between the logic semiconductor chip and the power semiconductor chip(s) may only be possible via wires based on a wire bonding technique. In contrast to this, using the logic semiconductor chip 12 of the device 100, these electrical connections may be provided by contact clips. Compared to conventional logic semiconductor chips, the logic semiconductor chip 12 of the device 100 may thus provide the following technical effects. The specified technical effects are neither exclusive nor limiting. Examples of multichip devices including logic semiconductor chips in accordance with the disclosure and taking advantage of the technical effects are e.g. described in connection with FIGS. 5 and 7.

A first technical effect may be that the processes used for clip bonding the power semiconductor chips may also be used for clip bonding the logic semiconductor chip. A second technical effect may be that contact clips that may be used anyway for electrically coupling the power semiconductor chips may additionally be used for electrically coupling the logic semiconductor chip. For example, such extended functionality of the contact clip may be realized by increasing a size or surface area of the contact clip to additionally cover relevant contact electrodes of the logic semiconductor chip. A third technical effect may be that employing a contact clip for an electrical connection between the logic semiconductor chip and one or more of the power semiconductor chips may result in an increased area of the contact clip which may support a dissipation of heat in a direction away from operating components of the device and thus support a cooling of the device.

The geometric form of the contact electrode 14 illustrated in FIG. 1 is exemplary. Other geometries of the contact electrode 14 may be possible. In particular, an exposed surface of the contact electrode 14 may be required to provide a bonding area large enough for a solder dispensing act of a wire bonding technique. Contrarily, other contact electrodes configured for wire bonding techniques may not necessarily provide such required clip bonding areas. The top layer forming the periphery of the logic semiconductor chip 12 may e.g. include a passivation layer which may e.g. be fabricated from at least one of a nitride (e.g. silicon nitride) and an oxide (e.g. silicon oxide). In one example, the layer(s) of the contact electrode 14 may be applied to the top layer of the logic semiconductor chip 12, wherein the upper surface and the side surfaces of the contact electrode 14 may be exposed. In a further example, the side surfaces of the contact electrode 14 may at least partly be covered by the top layer of the logic semiconductor chip 12. Here, the upper surface of the contact electrode 14 even may be flush with the top layer of the logic semiconductor chip 12. In yet a further example, an additional solder stop layer may be arranged over the top layer of the logic semiconductor chip 12, wherein the contact electrode 14 may at least partly be exposed from the solder stop layer. The solder stop layer may be configured to prevent a solder material from uncontrolledly dissolving during a soldering act of a clip bonding technique. For example, the solder stop layer may include at least one of a photoresist material, imide, epoxy, duroplast, silicone, silicon nitride, etc.

The device 200 of FIG. 2 includes a logic semiconductor chip 12 having a contact electrode 14. The contact electrode 14 includes a contact layer 16, wherein the contact layer 16 includes at least one of copper and nickel. In particular, the contact electrode 14 may be configured to be electrically coupled to a contact clip based on a clip bonding technique. An exemplary technique for providing an electrical coupling between. the contact electrode 14 and a contact clip is described in connection with FIGS. 4A to 4E. The contact electrode 14 may provide similar technical effects as described in connection with FIG. 1.

In one example, the contact layer 16 may form the complete contact electrode 14. In further examples, the contact electrode 14 may include additional layers and may thus correspond to a layer stack. Here, the contact layer 16 may particularly represent a final layer having an exposed surface such that a contact clip or a material connecting the contact layer 16 and a contact clip may be directly applied to the exposed surface of the contact layer 16. The exposed surface of the contact layer 16 may include at least one of the top surface and one or more of the side surfaces of the contact electrode 14. For example, a thickness of the contact layer 16 may be in a range from about 1 micrometer to about 5 micrometer. The contact layer 16 may be manufactured based on at least one of sputtering, chemical vapor deposition, physical vapor deposition.

The device 300 of FIG. 3 includes a logic semiconductor chip 12 and a power semiconductor chip 18. The device 300 further includes a contact clip 20 which electrically couples the logic semiconductor chip 12 and the power semiconductor chip 18, in particular contact electrodes of the semiconductor chips. For example, the logic semiconductor chip 12 of the device 300 may be similar to one of the logic semiconductor chips 12 of the devices 100 and 200. Multichip devices which may be seen as a more detailed implementation of the device 300 are e.g. described in connection with FIGS. 5 and 7.

FIGS. 4A to 4E schematically illustrate an exemplary clip bonding technique which may be applied to a device in accordance with the disclosure. The described method qualitatively illustrates an exemplary fabrication of an electrical coupling between a contact electrode of a semiconductor chip and a lead via a contact clip. A similar clip connection may also be established between other components, for example between contact electrodes of different semiconductor chips, in particular between a logic semiconductor chip and a power semiconductor chip. The described method may at least partly be used for providing an electrical connection between a contact clip and a contact electrode of a logic semiconductor chip in accordance with the disclosure.

In FIG. 4A, a carrier may be provided. For example, the carrier may be a leadframe including a diepad 22 and one or more leads 24. The diepad 22 may include at least one substantially planar surface 26 for mounting a component. At least some of the leads 24 may be electrically coupled to the diepad 22.

In FIG. 4B, a first material layer 28 may be deposited over the planar surface 26 of the diepad 22. For example, the first material layer 28 may be an electrically conductive joining material that may include at least one of a solder, a soft solder, a diffusion solder, a solder paste, a nanopaste, an adhesive, an electrically conductive adhesive. In particular, any solder material capable of forming solder bonds may be used as a material. For example, the solder material may include at least one of Sn, SnAg, SnAu, In, InAg, InAu.

In FIG. 4C, a semiconductor chip 30 may be arranged over the diepad 22. For example, the semiconductor chip 30 may be a logic semiconductor chips in accordance with the disclosure. The semiconductor chip 30 may include a first contact electrode (not illustrated) facing the diepad 22 and a second contact electrode 32 facing away from the diepad 22. The semiconductor chip 30 may include further contact electrodes which are not illustrated for the sake of simplicity. The semiconductor chip 30 may be solder attached to the diepad 22, wherein the first contact electrode may be electrically coupled and attached to the diepad 22 via the first solder material 28.

In FIG. 4D, a second material layer 34 may be deposited over parts of the arrangement. In particular, the second material layer 34 may be a second electrically conductive joining material that may be similar to the first solder material 28 described in connection with FIG. 4B. The second solder material 34 may be deposited over the second contact electrode 32 of the semiconductor chip 30 and over optional further contact electrodes. In particular, the second solder material 34 may be deposited over the contact electrodes that are to be electrically connected to a contact clip later on. The second solder material 34 may also be deposited over one or more of the leads 24.

In FIG. 4E, a contact clip 36 may be arranged over the semiconductor chip 30 such that at least a part of the second solder material 34 may be arranged between the second contact electrode 32 and a contact area of the contact clip 36. In addition, the contact clip 36 may be arranged over the leads 24 such that the second solder material 34 may be arranged between one or more contact areas of the contact clip 36 and the leads 24 over which the second solder material 31 is arranged. The contact areas of the contact clip 36 may particularly include substantially planar surfaces.

In a further act, the second solder material 34 may be heated to a temperature T in order to firmly attach the contact clip 36 to the second contact electrode 32 of the semiconductor chip 30 and to the leads 24. During the same heating process, the semiconductor chip 30 may be firmly attached to the diepad 22 by the first solder material 28. For example, heating the solder material may be accomplished by placing the arrangement of FIG. 4E in a furnace (not illustrated). A maximum temperature applied by the furnace to the solder material may e.g. lie in a range from about 250° C. to about 350° C., more particular from about 270° C. to about 320° C. In one example, the time of heating may lie in a range from about 30 seconds to about 300 seconds, more particular from about 60 seconds to about 120 seconds.

During the heating act, the solder material may transform into a solder bond layer, in particular a diffusion solder bond layer. The solder material may start melting at the melting temperature of the solder material. The solder material may be exposed to a temperature T that may be higher than the melting temperature. Here, an intermetallic phase may be formed in the solder material by diffusion. After the heating act, the solder material may have been completely transformed into the intermetallic phase. The produced solder bond layer may thus be made of the intermetallic phase. For example, a thickness of the solder bond layer may be smaller than about 10 micrometer.

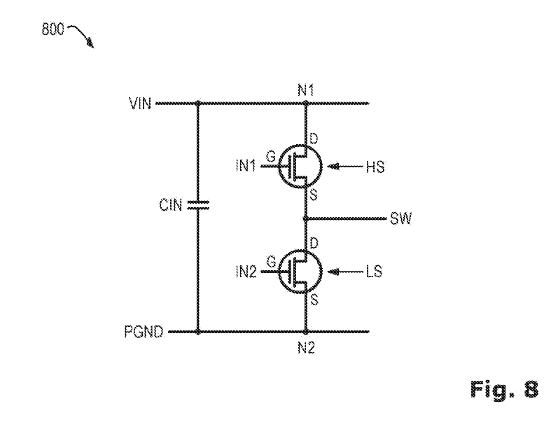

FIG. 5 schematically illustrates a top view of a device 500 in accordance with the disclosure. The device 500 may be seen as a more detailed implementation of the devices 100 to 300 such that details of the device 500 described below may be likewise applied to the devices 100 to 300. In particular, the device 500 may be configured to operate as a half bridge circuit similar to the half bridge circuit 800 of FIG. 8. Hence, the components of the device 500 specified in the following may particularly form a circuitry similar to FIG. 8 and may be interconnected accordingly. For ease of explanation and illustration certain device parts are not shown. For example, FIG. 5 does not illustrate an optional encapsulating material or an optional input capacitor CIN (see FIG. 8).

The device 500 may include a carrier that may be formed by a leadframe which may include a first diepad 40, a second diepad 42 and multiple leads (see PGND, GE, VCC, PHASE, etc.) arranged at a periphery of the leadframe. The device 500 may further include a first power semiconductor chip 44, a second power semiconductor chip 46 and a logic semiconductor chip 48. In addition, the device 500 may include a contact clip 50 indicated by dot-dashed lines and multiple wires providing electrical connections between components of the device 500.

The first power semiconductor chip 44 may be a first power transistor that may be arranged over the first diepad 40. In particular, the first power transistor 44 may operate as the high side switch. HS of the device 800 of FIG. 8. The first power transistor 44 may include a drain electrode (not illustrated) arranged over a main surface of the first power transistor 44 facing the first diepad 40. The drain electrode may be electrically coupled to one or more leads (see VIN) of the leadframe. The first power transistor 44 may further include a gate electrode 46, a source electrode 52 and one or more optional further contact electrodes 54 arranged over a main surface of the first power transistor 44 facing away from the first diepad 40. The gate electrode 46 may be electrically coupled to a contact electrode 60 of the logic semiconductor chip 48 by a wire based on a wire bonding technique. The source electrode 52 may be electrically coupled to the contact clip 50 based on a clip bonding technique. The optional one or more further contact electrodes 54 may be coupled to one or more leads of the leadframe depending on their respective functionality via one or more wires based on wire bonding technique. In the example of FIG. 5, a further contact electrode 54 may be electrically coupled to a lead (see PHASE) via a wire 68.

The second power semiconductor chip 56 may be a second power transistor that may be arranged over the second diepad 42. In particular, the second power semiconductor chip 56 may operate as the low side switch LS of the device 800 of FIG. 8. The second power transistor 56 may include a gate electrode (not illustrated) and a source electrode (not illustrated) arranged over a main surface of the second power transistor 56 facing the second diepad 42. The gate electrode may be electrically coupled to one or more leads (see GL) of the leadframe, and the source electrode may be electrically coupled to one or more leads (see PGND) of the leadframe. The second power transistor 56 may further include a drain electrode 58 arranged over a main surface facing away from the second diepad 42. The drain electrode 58 may be electrically coupled to the contact clip 50 based on a clip bonding technique. In addition, the drain electrode 58 may be electrically coupled to one or more leads (see VSW) of the leadframe via the contact clip 50.

The logic semiconductor chip 48 may be arranged over one of the first diepad 40 and the second diepad 42 or over an optional further diepad (not illustrated). The logic semiconductor chip 48 may be configured to control and/or drive at least one of the first power transistor 44 and the second power transistor 56. In particular, the logic semiconductor chip 48 may include a driver circuit configured to drive the high side switch HS and the low side switch LS of the half bridge circuit 800 of FIG. 8. The logic semiconductor chip 48 may include multiple contact electrodes that may be arranged over a main surface of the logic semiconductor chip 48 facing away from the diepad supporting the chip. In one example, the logic semiconductor chip 48 may be of lateral type such that all contact electrodes may be arranged on one main surface of the logic semiconductor chip 48.

The logic semiconductor chip 48 may include a first contact electrode 60 that may be electrically coupled to the gate electrode 46 of the first power transistor 44 via a wire based on a wire bonding technique. The logic semiconductor chip 48 may further include a second contact electrode 62 that may be electrically coupled to the contact clip 50 based on a clip bonding technique. In addition, the logic semiconductor chip 48 may include various (signal and power) input and output contact electrodes for controlling an operation of the device 500 similar to the half bridge circuit 800 of FIG. 8. These various contact electrodes may be electrically coupled to one or more leads of the leadframe (see e.g. PHASE, GL, BOOT, LGND, VCC, PWM, EN, GL), for example via wires based on a wire bonding technique.

The second contact electrode 62 of the logic semiconductor chip 48 may be similar to one of the contact electrodes 14 of the devices 100 to 300 in FIGS. 1 to 3. For example, the second contact electrode 62 may be configured to receive a sensing signal from the first power transistor 44 via the contact clip 50. The sensing signal may be based on a physical parameter of the first power transistor 44 and may represent information about a physical property of the first power transistor 44 that can be quantified by a measurement. In general, the physical parameter may include at least one of an electrical potential of the first power transistor 44, an electrical current of the first power transistor 44, and a temperature of the first power transistor 44.

In the example of FIG. 5, the contact clip 50 may be configured to provide a sensing signal to the second contact electrode 62 that may represent an electrical potential of the source electrode 52 of the first power transistor 44. In the example of FIG. 5, the contact clip 50 may be formed contiguous as a single piece. Since the contact clip 50 may be electrically conductive, the source electrode 52 of the first power transistor 44, the drain electrode 58 of the second power transistor 56 and the second contact electrode 62 of the logic semiconductor chip 48 may be electrically coupled and have a same electrical potential.

In further examples, the contact clip 50 may also consist of multiple pieces. With regard to the device 500, a first piece of the contact clip 50 may e.g. provide an electrical coupling required for an operation of the half bridge circuit, for example between the source electrode 52 of the first power transistor 44 and the drain electrode 58 of the second power transistor 56. In addition, a second piece of the contact clip 50 may be electrically insulated from the first piece and may provide a sensing signal from at least one of the first power transistor 44 and the second power transistor 56 to the logic semiconductor chip 48. Here, the sensing signal may also differ from the sensing signal representing an electric potential of the source electrode 52 and may, for example, be based on an electric current or a temperature of one of the power transistors.

The sensing signal provided by the contact clip 50 may be used to control and monitor the state of, for example, the first power transistor 44. For this purpose, the logic semiconductor chip 48 may be configured to generate a control signal and to provide the control signal to relevant components performing the control of the first power transistor 44. For example, a sensed electrical potential of the source electrode 52 of the first power transistor 44 may be used to generate a control signal that may be used by a gate driver circuit to control the gate electrode 46 of the first power transistor 44. The gate driver circuit may be included in the logic semiconductor chip 48. The control signal may e.g. be transmitted from the contact electrode 60 of the logic semiconductor chip 48 to the gate electrode 46 of the first power transistor 44 via the interconnecting wire. In particular, a measured electrical potential U_{S} at the source electrode 52 of the first power transistor 44 may be used to correct a voltage U_{G} that may have been applied to the gate electrode 46 of the first power transistor 44 without taking into account the sensing signal. A corrected value for control purposes that may be applied to the gate electrode 46 of the first power transistor 44 may thus have a value of U_{G}−U_{S} in one example.

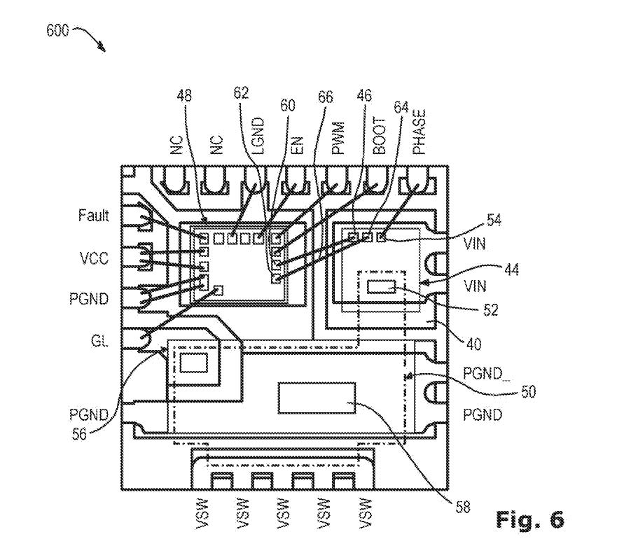

FIG. 6 schematically illustrates a top view of a device 600. The devices 500 and 600 may represent a similar circuitry. Comments made in connection with FIG. 5 may therefore also hold true for FIG. 6. In particular, the device 600 may also be configured to operate as a half bridge circuit similar to the half bridge circuit 800 of FIG. 8.

The device 600 may include a first power transistor 44, a second power transistor 56 and a logic semiconductor chip 48. The second power transistor 56 and the logic semiconductor chip 48 of the device 600 may be similar to respective components of the device 500. Compared to the device 500, the first power transistor 44 of the device 600 may include a further contact electrode 64 that may be arranged over a main surface of the first power transistor 44 facing away from the first diepad 40. In particular, the further contact electrode 64 may be configured to provide a sensing signal based on a physical parameter of the first power transistor 44. The further contact electrode 64 may be electrically coupled to the second contact electrode 62 of the logic semiconductor chip 48 via a wire 66 based on a wire bonding technique.

In one example, the further contact electrode 64 may be configured to provide a sensing signal that may represent an electrical potential of the source electrode 52 of the first power transistor 44. That is, the electrical coupling between the further contact electrode 64 of the first power transistor 44 and the second contact electrode 62 of the logic semiconductor chip 48 via the wire 66 in FIG. 6 may correspond to the electrical coupling between the source electrode 52 of the first power transistor 44 and the second contact electrode 62 of the logic semiconductor chip 48 via the contact clip 52 in FIG. 5. In comparison to FIG. 5, the design of the contact clip 50 of the device 600 may thus be amended such that the contact clip 50 is not electrically coupled to the second contact electrode 62 of the logic semiconductor chip 48. For example, amending the shape of the contact clip 50 may correspond to decreasing a surface area of the contact clip 50 such that the second contact electrode 62 of the logic semiconductor chip 48 is not covered by the contact clip 50, but may instead be electrically coupled to the wire 66.

Compared so the device 600 of FIG. 6, the device 500 of FIG. 5 may provide the following technical effects similar to the technical effects discussed in connection with the device 100 of FIG. 1. First, according to FIG. 5, a clip bonding process for providing an electrical coupling between the source electrode 52 of the first power transistor 44 and the drain electrode 58 of the second power transistor 56 may additionally be used to establish an electrical coupling for providing a sensing signal from the source electrode 52 of the first power transistor 44 to the second contact electrode 62 of the logic semiconductor chip 48. An additional wire bonding process as required in FIG. 6 (see wire 66) may thus be avoided. Second, in FIG. 5, the contact clip 50 already used for specific electrical connections may additionally be used to form an electrical coupling between the second contact electrode 62 and the source electrode 52.

Hence, no additional coupling element (see wire 66) may be necessary as in FIG. 6. Third, by providing the additional electrical coupling between the contact electrode 62 and the source electrode 52 as shown in FIG. 5, a surface area of the contact clip 50 may be increased which may improve a desired heat dissipation.

FIG. 7 schematically illustrates a top view of a device 700 in accordance with the disclosure. The devices 500 and 700 may represent a similar circuitry. Comments made in connection with FIG. 5 may thus also hold true for FIG. 7. In particular, the device 700 may be configured to operate as a half bridge circuit similar to the half bridge circuit 800 of FIG. 8. In FIG. 5, the contact electrode 54 of the first power transistor 14 may be electrically coupled to a lead (see PHASE) of the leadframe via a wire 68. Compared to FIG. 5, the surface area of the contact clip 50 of the device 700 may be increased such that the contact clip 50 may provide the electrical coupling between the contact electrode 54 of the first power transistor 44 and the lead (see PHASE). That is, using the contact clip 50 of FIG. 7, the wire 68 of FIG. 5 and an associated wire bonding process may be avoided. For the case of an electrically conductive contact clip 50, the lead (see PHASE) and the contact electrode 54 and the source electrode 52 may have a similar electrical potential. In one example, the lead (see PHASE) may be electrically coupled to an external controller and may serve for a transmission of a phase signal to the external controller.

FIG. 8 illustrates a schematic diagram of a half bridge circuit 800. The half bridge circuit 800 may include switches HS and LS connected in series and arranged between nodes N1 and N2. The switches may be a high side switch HS and a low side switch LS. In the example of FIG. 8, the switches HS and LS may be MOSFETs, each having a gate electrode G, a drain electrode D and a source S electrode. Furthermore, the half bridge circuit 800 may include an input capacitor CIN that may be coupled between a positive input VIN and a negative input PGND of the half bride circuit 800. In general, the types and number of semiconductor chips forming the half bridge circuit 800 may depend on the particular application for which the considered device may be designed.

The drain terminal D of the high side switch HS may be electrically connected to the positive input VIM of the half bridge circuit 800. The source terminal S of the high side switch HS may be electrically connected to the drain terminal D of the low side switch IS to form an output SW of the half bridge circuit 800. The source terminal S of the low side switch LS may be electrically connected to the negative input PGND. The transistor gates C may serve as control signal inputs IN1, IN2. In a further example, the MOSFETs may be replaced by IGBTs, wherein the collector connections of the IGBTs may correspond to the drain connections of the MOSFETs, and the emitter connections of the IGBTs may correspond to the source connections of the MOSFETs.

The half bridge circuit 800 may further include a logic semiconductor chip (not illustrated) with various (signal and power) inputs and outputs for controlling an operation of the half bridge circuit 800. In particular, the logic semiconductor chip may include a driver circuit configured to drive the gates G of the high side switch HS and the low side switch LS, for example via the inputs IN1, IN2.

Constant electrical potentials may be applied to the nodes N1 and N2. For example, a high potential VIN, such as 10, 12, 18, 50, 110, 230, 500 or 1000 V or any other potential, may be applied to the node N1 and a low electrical potential PGND, for example 0 V, may be applied to the node N2. The switches HS and LS may be switched at frequencies in the range from 1 kHz to 100 MHz, but the switching frequencies may also be outside this range. This means that a varying electrical potential may be applied to the node SW arranged. between the switches HS and LS during an operation of the half bridge. The potential of the node SW may vary in the range between the low and the high electrical potential.

The half bridge circuit 800 may e.g. be implemented in electronic circuits for converting DC voltages, i.e. DC-DC converters. DC-DC converters may be used to convert a DC input voltage provided by e.g. a battery into a DC output voltage matched to the demand of electronic circuits connected downstream. DC-DC converters may be embodied as step down converters, in which the output voltage is less than the input voltage, or as step up converters, in which the output voltage is greater than the input voltage. Frequencies of several MHz or higher may be applied to DC-DC converters. In addition, currents of up to 100 A or even. higher may flow through the DC-DC converters.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the term “exemplary” is merely meant as an example, rather than the best or optimal. It is also to be appreciated that features and/or elements depicted herein are illustrated with particular dimensions relative to each other for purposes of simplicity and ease of understanding and that actual dimensions may differ from that illustrated herein.

Although specific aspects have been illustrated and described herein, it will be appreciated by those of ordinary skill in the art that a variety of alternate and/or equivalent implementations may be substituted for the specific aspects shown and described without departing from the concept of the disclosure. This application is intended to cover any adaptations or variations of the specific aspects discussed herein. Therefore, it is intended that this disclosure be limited only by the claims and the equivalents thereof.

What is claimed is:

1. A device, comprising:
a logic semiconductor chip comprising a first contact electrode, wherein the first contact electrode is configured to be electrically coupled to a contact clip based on a clip bonding technique.

2. The device of claim 1, wherein the first contact electrode comprises a first contact layer, wherein the first contact layer comprises at least one of copper and nickel.

3. The device of claim 2, wherein a thickness of the first contact layer is in a range from 1 micrometer to 5 micrometers.

4. The device of claim 1, wherein the logic semiconductor chip comprises a second contact electrode configured to be electrically coupled to a wire based on a wire bonding technique.

5. The device of claim 4, wherein the second contact electrode comprises a second contact layer, wherein the second contact layer comprises aluminum.

6. The device of claim 1, wherein the logic semiconductor chip comprises at least one of a logic integrated circuit, a control integrated circuit, and a driver integrated circuit.

7. The device of claim 1, further comprising:
a contact clip electrically coupled to the first contact electrode.

8. The device of claim 7, further comprising:
a solder material arranged between the contact clip and the first contact electrode.

9. The device of claim 7, further comprising:
a first power semiconductor chip,
wherein the logic semiconductor chip and the first power semiconductor chip are electrically coupled by the contact clip.

10. The device of claim 9, wherein the first power semiconductor chip comprises a power transistor and the logic semiconductor chip comprises a gate driver configured to drive a gate of the power transistor.

11. The device of claim 9, wherein the contact clip is configured to provide a sensing signal from the first power semiconductor chip to the logic semiconductor chip, wherein the sensing signal is based on a physical parameter of the first power semiconductor chip.

12. The device of claim 11, wherein the physical parameter comprises at least one of an electrical potential of the first power semiconductor chip, an electrical current of the first power semiconductor chip, and a temperature of the first power semiconductor chip.

13. The device of claim 11, wherein the logic semiconductor chip is configured to generate a control signal based on the sensing signal, wherein the control signal is configured to control the first power semiconductor chip.

14. The device of claim 9, further comprising:
a second power semiconductor chip,
wherein the first power semiconductor chip and the second power semiconductor chip are electrically coupled by the contact clip.

15. The device of claim 14, wherein the first power semiconductor chip comprises a low side switch of a half bridge circuit and the second power semiconductor chip comprises a high side switch of the half bridge circuit.

16. A device, comprising:
a logic semiconductor chip comprising a contact electrode, wherein the contact electrode comprises a contact layer, wherein the contact layer comprises at least one of copper and nickel.

17. The device of claim 16, wherein the contact electrode is located at a periphery of the logic semiconductor chip and is configured to provide an electrical coupling to an internal electronic structure of the logic semiconductor chip from outside of the logic semiconductor chip.

18. The device of claim 16, further comprising:
a solder stop layer arranged over the contact electrode, wherein the contact electrode is at least partly exposed from the solder stop layer.

19. The device of claim 16, wherein the logic semiconductor chip is a lateral semiconductor chip.

20. A device, comprising:
a logic semiconductor chip;
a power semiconductor chip; and
a contact clip electrically coupling the logic semiconductor chip and the power semiconductor chip.

21. The device of claim 20, wherein the contact clip is configured to provide a sensing signal from the power semiconductor chip to the logic semiconductor chip, wherein the sensing signal is based on a physical parameter of the power semiconductor chip.

22. The device of claim 21, wherein the logic semiconductor chip is configured to generate a control signal based on the sensing signal, wherein the control signal is configured to control the power semiconductor chip.
